(19) United States
(12) Patent Application Publication
(10) Pub. No.: US 2026/0096130 A1
(43) Pub. Date: Apr. 2, 2026

(54) HEMT DEVICE HAVING LOW CONDUCTION LOSSES AND MANUFACTURING PROCESS THEREOF

(71) Applicant: STMicroelectronics S.r.l., Agrate Brianza (IT)

(72) Inventors: Ferdinando IUCOLANO, Gravina di Catania (IT); Andrea SEVERINO, Aci Sant'Antonio (IT); Giuseppe GRECO, Misterbianco (IT); Fabrizio ROCCAFORTE, Mascalucia (IT)

(73) Assignee: STMicroelectronics S.r.l., Agrate Brianza (IT)

(21) Appl. No.: 19/413,745

(22) Filed: Dec. 9, 2025

Related U.S. Application Data
(62) Division of application No. 18/167,623, filed on Feb. 10, 2023, now Pat. No. 12,520,517.

(30) Foreign Application Priority Data
Feb. 16, 2022 (IT) 102022000002846

(51) Int. Cl. H10D 30/47; H10D 30/01; H10D 62/832

(52) U.S. Cl. CPC H10D 30/475; H10D 30/015; H10D 62/8325

(57) ABSTRACT

A manufacturing process forms an HEMT device. For the manufacturing process includes forming, from a wafer of silicon carbide having a surface, an epitaxial layer of silicon carbide on the surface of the wafer A semiconductive heterostructure is formed on the epitaxial layer, and the wafer of silicon carbide is removed.

### BACKGROUND

### Technical Field

The present disclosure relates to a high electron mobility transistor (HEMT) device having low conduction losses and to the manufacturing process thereof.

### Description of the Related Art

HEMT devices are known wherein a conductive channel is based on the formation of a two-dimensional electron gas (2DEG) having high mobility at a heterojunction, that is at the interface between semiconductor materials having different band gap. For example, HEMT devices based on the heterojunction between an aluminum gallium nitride (AlGaN) layer and a gallium nitride (GaN) layer are known.

The HEMT devices based on AlGaN/GaN heterojunctions or heterostructures offer several advantages that make them particularly suitable and widely used for different applications. For example, the high breakdown voltage of the HEMT devices is exploited for high-performance power switches; the high mobility of the electrons in the conductive channel allows high-frequency amplifiers to be provided; in addition, the high concentration of electrons in the 2DEG allows a low ON-state resistance (RON) to be obtained.

Moreover, the HEMT devices for radio frequency (RF) applications typically have better RF performances with respect to similar silicon LDMOS devices.

In known HEMT devices, the heterostructure extends on a substrate. In order to reduce, in use, the conductive losses through the substrate, it is desired that the substrate has a high resistivity.

According to one approach, during the manufacturing process of known HEMT devices, the heterostructure is grown on a resistive silicon substrate. However, the heterostructure of the known HEMT devices grown on silicon is subject to a high concentration of crystallographic defects. Consequently, the corresponding HEMT devices have low electrical performances, in use.

According to a different approach, during the manufacturing process of the known HEMT devices, the heterostructure is grown directly on a semi-insulating silicon carbide wafer. However, the semi-insulating silicon carbide wafers have a high cost, especially in the case of wafers having large dimensions, for example having a diameter of 200 mm. Consequently, the HEMT devices obtained from semi-insulating silicon carbide wafers have a high manufacturing cost.

### BRIEF SUMMARY

Embodiments of the present disclosure overcome the disadvantages of the prior art.

According to the present disclosure a HEMT device and a manufacturing process thereof are therefore provided. In one embodiment, the process includes forming an epitaxial layer of silicon carbide on a surface of a wafer of silicon carbide, forming a semiconductive heterostructure on the epitaxial layer, and removing the wafer of silicon carbide.

### BRIEF DESCRIPTION OF THE SEVERAL VIEWS OF THE DRAWINGS

For a better understanding of the present disclosure, an embodiment thereof is now described, purely by way of non-limiting example, with reference to the attached drawings, wherein:

FIGS. 1-5 show cross-sections of a work body in successive manufacturing steps, according to one embodiment; and

FIG. 6 shows a cross-section of an HEMT device, according to one embodiment.

### DETAILED DESCRIPTION

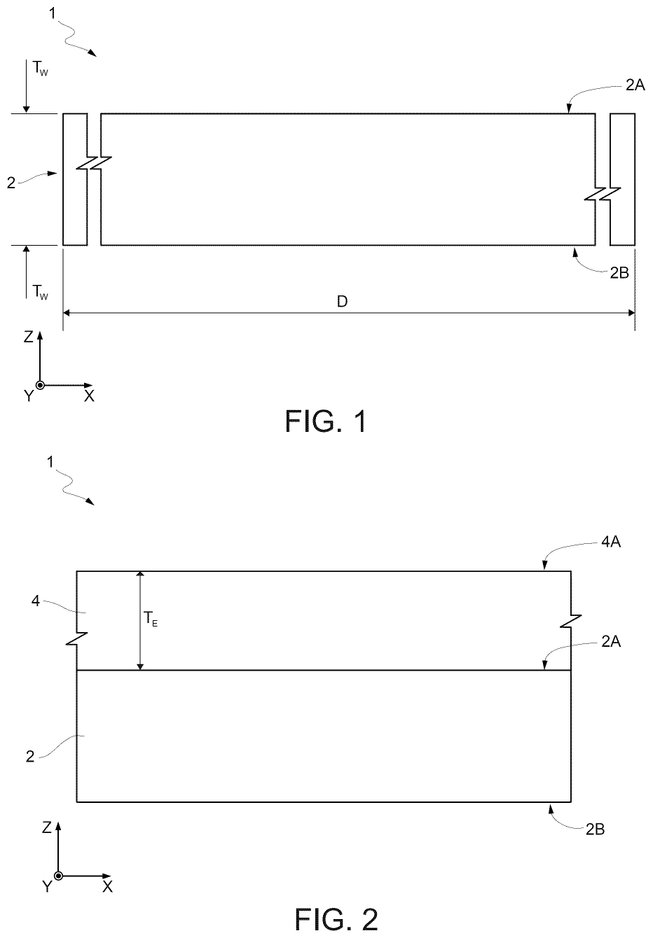

FIG. 1 shows a work body 1 including a wafer 2 having a front surface 2A and a back surface 2B, in a Cartesian reference system XYZ including a first axis X, a second axis Y and a third axis Z. The front surface 2A and the back surface 2B of the wafer 2 respectively form a front surface and a back surface of the work body 1.

The wafer 2 is of silicon carbide (SiC) in one of its polytypes, for example 3C, 4H, 6H, here of the polytype 4H.

The wafer 2 is a SiC wafer of conductive type, for example having a conductivity of n-type or p-type, here of n-type. In detail, the wafer 2 has a resistivity lower than 0.1 Ω·cm, for example between 0.005 Ω·cm and 0.05 Ω·cm.

For example, the wafer 2 may have a concentration of n-type doping atoms between 1.1017 atoms/cm³ and 1·10¹⁹ atoms/cm³.

In this embodiment, the wafer 2 has a cut angle such that the front surface 2A of the wafer 2 is tilted by a non-zero angle with respect to a C-type plane or face of the crystallographic structure of the silicon carbide.

In detail, the front surface 2A of the wafer 2 is tilted by the cut angle with respect to the face (000-1) of the 4H—SiC, wherein the values 0, 0, 0, −1 respectively indicate the indices h, k, i, l of Bravais-Miller.

In practice, the surface 2A of the wafer 2 is an off-axis face of the wafer 2, in particular having a cut angle lower than 4°.

However, the surface 2A of the wafer 2 may have a different cut angle, for example equal to zero; that is, the surface 2A of the wafer 2 may be parallel to the face (000-1) of the 4H—SiC.

The wafer 2 has a thickness T_{W} along the third axis Z, for example between 100 μm and 500 μm, in particular between 250 μm and 350 μm.

The wafer 2 may have a width or diameter D, parallel to the first axis X, that is high, for example between 50 mm and 200 mm.

The following FIGS. 2-5 show, for simplicity, only a reduced portion, along the first axis X, of the wafer 2.

In FIG. 2, an epitaxial layer 4 of silicon carbide is grown on the front surface 2A of the wafer 2. The epitaxial layer 4 has a surface 4A and a thickness T_{E}, along the third axis Z, for example between 60 μm and 100 μm. The surface 4A of the epitaxial layer 4 thus forms a new front surface of the work body 1.

The epitaxial layer 4 is formed by highly resistive silicon carbide, for example having a resistivity greater than 1·10⁴ Ω·cm.

In practice, the epitaxial layer 4 has a greater resistivity than the wafer 2.

In detail, the epitaxial layer 4 is grown so as to have a low concentration of doping atoms.

The epitaxial layer 4 may have a concentration of doping atoms, for example of n-type such as nitrogen atoms, lower than 5·10¹⁴ atoms/cm³, in particular between 5·10¹¹ and 5·10¹³ atoms/cm³.

The epitaxial layer 4 may maintain the crystallographic orientation of the front surface 2A of the wafer 2. Consequently, in this embodiment, the surface 4A of the epitaxial layer 4 may maintain the same cut angle as the front surface 2A of the wafer 2.

In practice, the crystalline structure of the epitaxial layer 4 changes as a function of the cut angle of the front surface 2A of the wafer 2.

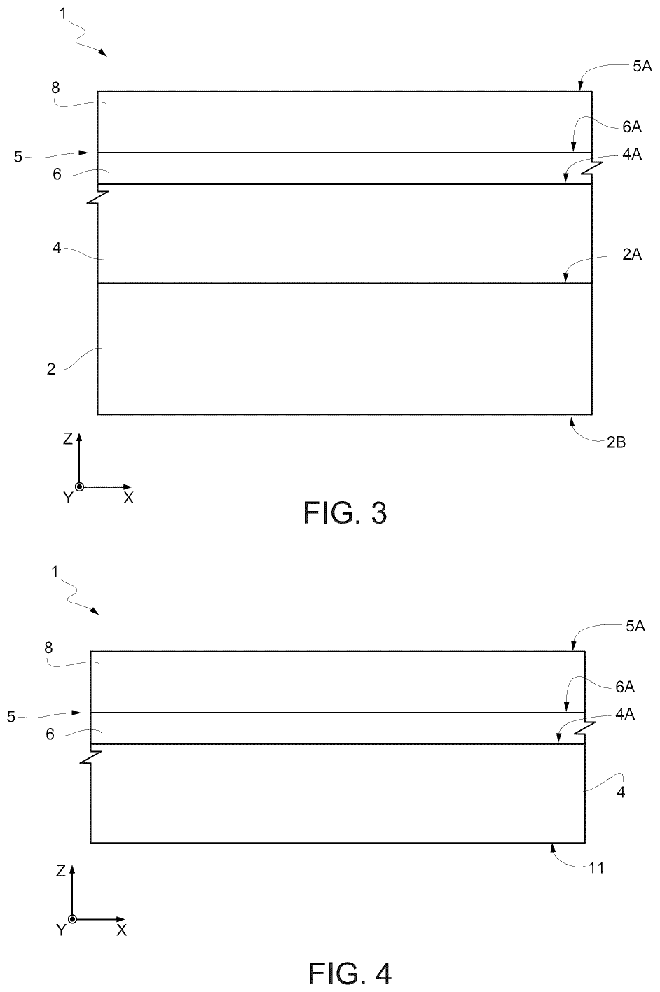

In FIG. 3, a heterostructure 5 is grown on the surface 4A of the epitaxial layer 4. The heterostructure 5 has a surface 5A which forms a new front surface of the work body 1.

The heterostructure 5 comprises compound semiconductor materials including elements of the group III-V.

In detail, the heterostructure 5 is formed by a channel layer 6 of a first semiconductor material, for example gallium nitride (GaN) or an alloy including gallium nitride such as InGaN, here of intrinsic gallium nitride (GaN), extending on the epitaxial layer 4, and by a barrier layer 8 of a second semiconductor material, for example a compound based on a ternary or quaternary alloy of gallium nitride, such as AlₓGa₁₋ₓN, AlInGaN, InₓGa₁₋ₓN, AlₓIn₁₋ₓAl, AlScN, here of intrinsic aluminum gallium nitride (AlGaN), extending on the channel layer 6.

In detail, the channel layer 6 extends on the surface 4A of the epitaxial layer 4, in direct contact therewith.

The barrier layer 8 extends on the channel layer 6, in direct contact therewith; the heterostructure 5 therefore comprises an interface 6A between the channel layer 6 and the barrier layer 8.

Subsequently, FIG. 4, the wafer 2 is removed. For example, the wafer 2 may be removed through a thinning process such as mechanical grinding, chemical mechanical polishing (CMP) or slicing through a laser process.

To verify the complete removal of the wafer 2, the state of removal of the wafer 2 may be controlled through an electrical measurement, for example through a mercury probe C-V measurement, or through an optical measurement.

In practice, the epitaxial layer 4 now forms the back surface, here indicated by 11, of the work body 1.

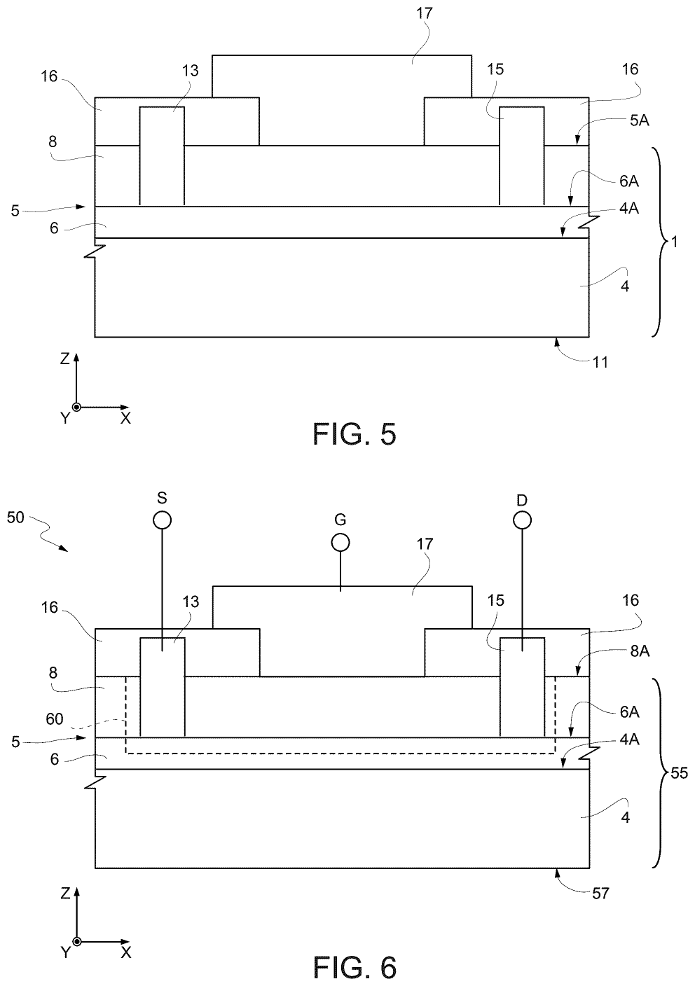

In FIG. 5, a source region 13, a drain region 15, an insulation or passivation layer 16 and a gate region 17 are formed.

The source region 13 and the drain region 15 are of conductive material and extend in direct electrical contact with the heterostructure 5, in particular in ohmic contact with the channel layer 6.

In this embodiment, the source region 13 and the drain region 15 extend in depth into the heterostructure 5, up to the interface 6A. However, the source region 13 and the drain region 15 may extend into the heterostructure 5 up to a different depth, depending on the specific application.

The insulation layer 16 is of dielectric material, for example silicon nitride or silicon oxide and extends on the surface 5A of the heterostructure 5.

The gate region 17 comprises conductive material and extends through the insulation layer 16, between the source region 13 and the drain region 15, in direct electrical contact with the heterostructure 5.

For example, the gate region 17 may be formed by a single conductive layer or by a stack of conductive layers, including for example gold, nickel, titanium, etc., depending on the specific application.

According to an embodiment, the gate region 17 may be formed by an insulating layer, in direct contact with the heterostructure 5, and one or more conductive layers extending on the insulating layer, so that the one or more conductive layers are not in direct electrical contact with the heterostructure 5.

According to an embodiment, the gate region 17 may also partially extend within the heterostructure 5, depending on the specific application.

The work body 1 is then subject to final manufacturing steps such as dicing and electrical connection, of a per se known type, thus forming a HEMT device 50 (FIG. 6).

The HEMT device 50 is particularly suitable for being used in RF applications, such as for example 4G and 5G base stations, including technology evolutions and variants, mobile phones, RF heat treatment devices, drying and heating devices, devices and systems for avionics, L- and S-band radar, and the like.

The HEMT device 50 is formed in a body or die 55 having a back surface 57 and includes an epitaxial substrate 4 (corresponding to the epitaxial layer 4 and therefore indicated by the same reference number) and the heterostructure 5 extending in direct contact on the epitaxial substrate 4.

The epitaxial substrate 4 has a thickness along the third axis Z comprised, for example, between 60 μm and 100 μm, and forms the back surface 57 of the body 55.

In practice, the back surface 57 is an external surface of the body 55, delimiting the body 55 at the back.

The source region 13, the drain region 15 and the gate region 17 respectively form a source electrode S, a drain electrode D and a gate electrode G of the HEMT device 50.

The body 55 accommodates an active region 60, indicated by a dashed line in FIG. 6, which accommodates, in use, a conductive channel of the HEMT device 50.

In use, the fact that the epitaxial substrate 4 has a low concentration of impurities and therefore a high resistivity, causes the HEMT device 50 to have low conductive losses through the epitaxial substrate 4, especially in radiofrequency applications.

In fact, in radiofrequency applications, the back surface 57 of the HEMT device 50 may be used, for example, as the RF reference (ground) terminal of the HEMT device 50. In this case, the high resistivity of the epitaxial substrate 4 allows to reduce the conductive losses between the gate region 17 and the back surface 57 and thus improve the RF performances of the HEMT device 50.

Furthermore, the fact that the manufacturing of the HEMT device 50 starts from the wafer 2, which is of conductive type, allows the use of SiC wafers having a large diameter and at the same time having a low cost, for example the diameter D of the wafer 2 may be up to 200 mm, or even greater.

The possibility of using SiC wafers having large dimension and a low cost allows the manufacturing costs of the HEMT device 50 to be further reduced.

Finally, it is clear that modifications and variations may be made to the HEMT device 50 and to the manufacturing process thereof described and illustrated herein without thereby departing from the scope of the present disclosure, as defined in the attached claims.

For example, the channel layer 6 and the barrier layer 8 may each be formed by a plurality of layers superimposed on each other, for example one or more layers of GaN, or GaN-based alloys, suitably doped or of intrinsic type, depending on the specific application.

For example, the HEMT device 50 may be of normally-off or normally-on type.

For example, the source region 13, the drain region 15 and the gate region 17 may have shapes other than what has been shown, depending on the specific application and on the specific design parameters.

The source region 13, the drain region 15 and the gate region 17 may extend along the second axis Y according to different shapes and configurations, depending on the specific application. For example, in a top-plan view, here not shown, the source region 13, the drain region 15 and the gate region 17 may have a shape of elongated strips along the second axis Y, or may have a circular shape or any other shape, regular or non-regular.

For example, the source region 13, the drain region 15 and the gate region 17 may each form a portion of a respective region having a more complex shape and electrically connected to other portions through specific electrical connections.

The manufacturing steps shown in FIGS. 1-5 may be performed in a different order from that shown. For example, the source region 13, the drain region 15 and the gate region 17 may be formed before the wafer 2 is removed. Otherwise, the wafer 2 may be removed before the heterostructure 5 is grown.

In one embodiment, manufacturing process of a HEMT device (50), from a wafer (2) of silicon carbide having a surface (2A), may include forming an epitaxial layer (4) of silicon carbide on the surface (2A) of the wafer (2), forming a semiconductive heterostructure (62) on the epitaxial layer, and removing the wafer of silicon carbide.

The wafer of silicon carbide may have a first resistivity and the epitaxial layer may have a second resistivity greater than the first resistivity.

The wafer of silicon carbide may have a resistivity lower than 0.1 Ω·cm.

The epitaxial layer may have a concentration of doping atoms lower than 5·10¹⁴ atoms/cm³.

The surface (2A) of the wafer of silicon carbide may have a non-zero cut angle with respect to a C-type plane of the wafer (2).

The cut angle may be lower than 4°.

The epitaxial layer (4) may have a thickness between 60 μm and 100 μm.

In one embodiment, a HEMT device (50) may be formed in a semiconductor body (55) having an external surface (57). The HEMT device may include a substrate (4) of silicon carbide forming the external surface of the semiconductor body and a semiconductive heterostructure (5) extending on the substrate. The substrate (4) is of epitaxial type.

The substrate may have a concentration of doping atoms lower than 5·10¹⁴ atoms/cm³.

The substrate (4) may have a surface (4A) that is off-axis with respect to a C-type plane of the silicon carbide. The semiconductive heterostructure (5) extends in direct contact on the surface (4A) of the substrate.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A HEMT device, comprising:
a semiconductor body including a substrate of silicon carbide forming an external surface of the semiconductor body; and
a semiconductive heterostructure extending on the substrate,
wherein the substrate is of epitaxial type.

2. The HEMT device according to claim 1, wherein the substrate has a concentration of doping atoms lower than 5·10\hat{ }14 atoms/cm³.

3. The HEMT device according to claim 1, wherein the substrate has a surface that is off-axis with respect to a C-type plane of the silicon carbide, the semiconductive heterostructure extending in direct contact on the surface of the substrate.

4. The HEMT device of claim 1, wherein the substrate has a resistivity greater than 10 kΩ·cm.

5. The HEMT device of claim 1, wherein the surface of the substrate has a non-zero angle with respect to a C-type plane of the silicon carbide.

6. The HEMT device of claim 5, wherein the angle is lower than 4°.

7. The HEMT device of claim 6, wherein the substrate has a thickness between 60 μm and 100 μm.

8. An HEMT device, comprising:
an epitaxial layer of SiC;
a ground terminal on a back surface of the epitaxial layer of SiC;
a semiconductor heterostructure on a front surface of the epitaxial layer of SiC including:
a channel layer on the front surface of the epitaxial layer of SiC; and
a barrier layer on the channel layer.

9. The HEMT device of claim 8, comprising a source terminal and a drain terminal extending through the barrier layer.

10. The HEMT device of claim 9, wherein the source terminal and the drain terminal terminate at an interface between the barrier layer and the channel layer.

11. The HEMT device of claim 10, further comprising an insulating layer on the barrier layer and on the source terminal and the drain terminal.

12. The HEMT device of claim 10, further comprising a gate terminal extending through the insulating layer and contacting the barrier layer.

13. The HEMT device according to claim 8, wherein the substrate has a concentration of doping atoms lower than 5·10\hat{ }14 atoms/cm³.

14. The HEMT device according to claim 8, wherein the substrate has a surface that is off-axis with respect to a C-type plane of the silicon carbide, the semiconductive heterostructure extending in direct contact on the surface of the substrate.

15. The HEMT device of claim 8, wherein the substrate has a resistivity greater than 10 kΩ·cm.

16. The HEMT device of claim 8, wherein the epitaxial layer has a concentration of doping atoms between 5·10¹¹ and 5·10¹³ atoms/cm³.

17. The HEMT device of claim 8, wherein the surface of the substrate has a non-zero angle with respect to a C-type plane of the silicon carbide.

18. An HEMT device, comprising:
an epitaxial layer of SiC;
a heterostructure on the epitaxial layer of SiC; and
a source terminal and a drain terminal extending into the heterostructure.

19. The HEMT device of claim 18, wherein the heterostructure includes a channel layer and a barrier layer.

20. The HEMT device of claim 18, wherein the surface of the substrate has a non-zero angle with respect to a C-type plane of the silicon carbide.
